(19) United States
(12) Patent Application Publication
(10) Pub. No.: US 2024/0295818 A1
(43) Pub. Date: Sep. 5, 2024

(54) UNDERLAYER COMPOUND FOR PHOTOLITHOGRAPHY, MULTILAYERED STRUCTURE FORMED USING THE SAME, AND METHOD FOR MANUFACTURING SEMICONDUCTOR DEVICES USING THE SAME

(71) Applicant: Inha University Research and Business Foundation, Incheon (KR)

(72) Inventors: Jinkyun LEE, Incheon (KR); Yejin KU, Incheon (KR); Min Seung KIM, Incheon (KR)

(73) Assignee: Inha University Research and Business Foundation, Incheon (KR)

(21) Appl. No.: 18/434,032

(22) Filed: Feb. 6, 2024

(30) Foreign Application Priority Data
Feb. 24, 2023 (KR) 10-2023-0025341
Dec. 1, 2023 (KR) 10-2023-0172321

(51) Int. Cl. G03F 7/11; G03F 7/004; G03F 7/16; G03F 7/20; G03F 7/32; H01L 21/027

(52) U.S. Cl. CPC G03F 7/11; G03F 7/0042; G03F 7/162; G03F 7/167; G03F 7/2004; G03F 7/2059; G03F 7/325; H01L 21/0274

(57) ABSTRACT

Provided is an underlayer which may improve the resolution and sensitivity of a resist film, suppress the collapse of a resist pattern and have improved etching resistance. The underlayer includes a crosslinked material of tin-oxo nanoclusters represented by Formula 1.

[(R—Sn)₁₂O₁₄(OH)₆]²⁺[Rx⁻]₂ [Formula 1]

In Formula 1, R is an alkyl group of 1 to 20 carbon atoms, and Rx⁻ is a counter anion and an alkylbenzene sulfonate anion.

### CROSS-REFERENCE TO RELATED APPLICATIONS

This U.S. non-provisional patent application claims priority under 35 U.S.C. § 119 of Korean Patent Application Nos. 10-2023-0025341, filed on Feb. 24, 2023, and 10-2023-0172321, filed on Dec. 1, 2023, the entire contents of which are hereby incorporated by reference.

### BACKGROUND

The present disclosure herein relates to an underlayer compound for photolithography used for the manufacture of a semiconductor device, a multilayered structure formed using the same, and a method for manufacturing a semiconductor device using the same.

This study was conducted with the support of Samsung Future Technology Promotion Project (project number: SRFC-TA1703-51).

Photolithography may include an exposing process and a developing process. The exposing process may include exposing a resist film to a specific wavelength of light to induce the change of the chemical structure of the resist film. The developing process may include the selective removal of the exposed part or the unexposed part of the resist film by using a solubility difference between the exposed part and the unexposed part.

Recently, as semiconductor devices are highly integrated and downsized, the line width of patterns in semiconductor devices is miniaturized. In order to form minute patterns, various studies are conducted to improve the resolution and sensitivity of resist patterns formed by photolithography and to suppress the collapse of resist patterns.

### SUMMARY

The present disclosure is to provide an underlayer compound, which may improve the resolution and sensitivity of a resist film, suppress the collapse of a resist pattern, and improve etching resistance, and a multilayered structure formed using the same, and a method for manufacturing a semiconductor device using the same.

The present disclosure is not limited to the aforementioned tasks, and unreferred other tasks may be clearly understood by a person skilled in the art from the description below.

A multilayered structure according to the inventive concept includes an underlayer on a lower layer, and a resist film on top of the underlayer, wherein the underlayer includes a crosslinked material of tin-oxo nanoclusters represented by Formula 1.

[(R—Sn)₁₂O₁₄(OH)₆]²⁺[Rx⁻]₂ [Formula 1]

In Formula 1, R is an alkyl group of 1 to 20 carbon atoms, and Rx⁻ is a counter anion and an alkylbenzene sulfonate anion.

A method for manufacturing a semiconductor device according to the inventive concept includes forming an underlayer on a lower layer, and forming a resist film on top of the underlayer. The underlayer includes a crosslinked material of tin-oxo nanoclusters represented by Formula 1 from each other.

An underlayer compound for photolithography according to the inventive concept includes a crosslinked material of tin-oxo nanoclusters represented by Formula 1 from each other.

### BRIEF DESCRIPTION OF THE FIGURES

The accompanying drawings are included to provide a further understanding of the inventive concept, and are incorporated in and constitute a part of this specification. The drawings illustrate example embodiments of the inventive concept and, together with the description, serve to explain principles of the inventive concept. In the drawings:

FIG. 1 is a diagram showing Fourier Transform Infrared (FTIR) spectrums of BTOC synthesized according to Synthetic Example 1 and DSBTOC synthesized according to Synthetic Example 2;

FIG. 2 to FIG. 4 are cross-sectional views showing multilayered structures formed using underlayer compounds according to embodiments of the inventive concept;

FIG. 5 to FIG. 10 are cross-sectional views showing a method for manufacturing a semiconductor device according to embodiments of the inventive concept;

FIG. 11 shows the images of negative tone resist patterns formed by an extreme ultraviolet lithography process of Experimental Example 2; and

FIG. 12 is a graph showing the evaluation results of the solubility of resist thin films according to Experimental Example 2.

### DETAILED DESCRIPTION

Preferred embodiments of the inventive concept will be explained with reference to the accompany drawings for sufficient understanding of the configurations and effects of the inventive concept. The inventive concept may, however, be embodied in various forms, have various modifications and should not be limited to the embodiments set forth herein. The embodiments are provided to complete the disclosure of the inventive concept through the explanation of the embodiments and to completely inform a person having ordinary knowledge in this technical field to which the inventive concept belongs.

The terminology used herein is for the purpose of describing example embodiments only and is not intended to limit the inventive concept. In the disclosure, the singular forms are intended to include the plural forms as well, unless the context clearly indicates otherwise. It will be further understood that the terms “comprises” and/or “comprising,” when used in this specification, specify the presence of stated elements, but do not preclude the presence or addition of one or more other elements.

In the present description, an alkyl group includes a linear, branched or cyclic monovalent saturated hydrocarbon group, unless otherwise indicated.

In the description, a case of not drawing a chemical bond at a position where a chemical bond is required, may mean that a hydrogen atom is bonded, unless otherwise defined.

Hereinafter, embodiments of the inventive concept will be explained in detail with reference to attached drawings. The same reference numerals are used for the same constituent elements on the drawings, and repeated explanation thereon will be omitted.

An underlayer compound according to embodiments of the inventive concept will be explained.

The underlayer compound according to embodiments of the inventive concept may be used for the manufacture of a semiconductor device and may be used in a photolithography process for the manufacture of a semiconductor device. The underlayer compound may be used, for example, in an extreme ultraviolet or e-beam lithography process. The extreme ultraviolet may mean ultraviolet having a wavelength of about 10 nm to about 124 nm, in detail, a wavelength of about 13.0 nm to about 13.9 nm, in more detail, a wavelength of about 13.4 nm to about 13.6 nm.

The underlayer compound may include a crosslinked material of tin-oxo nanoclusters represented by Formula 1 from each other.

[(R—Sn)₁₂O₁₄(OH)₆]²⁺[Rx⁻]₂ [Formula 1]

In Formula 1, R is an alkyl group of 1 to 20 carbon atoms, and Rx⁻ is a counter anion and an alkylbenzene sulfonate anion.

Rx may have a structure of Formula 2.

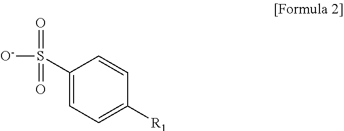

In Formula 2, R₁ is an alkyl group of 1 to 20 carbon atoms.

The tin-oxo nanoclusters represented by Formula 1 may have excellent absorption properties of ultraviolet, and through the absorption of ultraviolet photons, tin radicals may be produced. The tin radicals may be produced by removing the alkyl group (R) from tin elements in Formula 1. The tin-oxo nanoclusters may have a structure of Formula 1 in which at least one alkyl group (R) is removed from at least one tin element, and may include at least one tin radical.

The tin-oxo nanoclusters represented by Formula 1 may be crosslinked each other via the tin radicals. In an embodiment, the tin-oxo nanoclusters may be crosslinked through Sn-L-Sn connection, and L may be a connecting group represented by —O— or —CO— —O(C═O)O—. Accordingly, the underlayer compound may include a crosslinked structure of the tin-oxo nanoclusters represented by Formula 1, which crosslink each other via the tin radicals. By the removal of the alkyl group (R), the underlayer compound may have degraded solubility in an organic solvent.

In an embodiment, the underlayer compound may include a crosslinked material of tin-oxo nanoclusters represented by Formula 3.

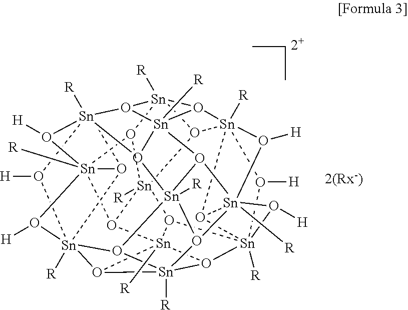

In Formula 3, R is a butyl group, and Rx⁻ is a counter anion represented by Formula 4.

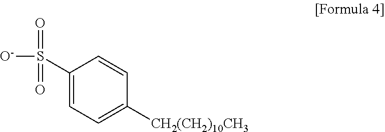

In an embodiment, the tin-oxo nanoclusters may have a structure of Formula 3, in which at least one alkyl group (R) is removed from at least one tin element, and may include at least one tin radical. The underlayer compound may include a crosslinked structure of the tin-oxo nanoclusters via the tin radicals.

### [Synthetic Example 1] Synthesis of Tin-Oxo Nanoclusters Having Butyl Group [(Bu-Sn)₁₂O₁₄(OH)₆]²⁺[OH⁻]₂ (BTOC) (Reaction 1)

To a 100 cm³ vial, butyl tin trichloride (3 g, 10.63 mmol) was injected and 0.5 M of an aqueous tetramethylammonium hydroxide solution (64 cm³) was added thereto, while vigorous stirring. The mixture thus produced was stirred at room temperature for about 1 hour, and a solid was obtained through filtration. The solid was washed several times with purified water and dried to provide [(Bu-Sn)₁₂O₁₄(OH)₆]²⁺[OH⁻]₂ (BTOC) as a white solid (1.8 g, yield: 69%).

IR [(KBr): Vₘₐₓ, (cm⁻¹)] 3245, 2957, 2925, 1464, 1378, 671, 548

### [Synthetic Example 2] Synthesis of Tin-Oxo Nanoclusters in which Counter Anion is Substituted with Dodecylbenzene Sulfonate [(Bu-Sn)₁₂O₁₄(OH)₆]²⁺[C₁₈H₂₉SO₃⁻]₂ (DSBTOC) (Reaction 1)

To a 20 cm³ vial, BTOC (1 g, 0.40 mmol) of Synthetic Example 1 and tetrahydrofuran (THF, 8 cm³) were added and stirred, and a solution obtained by mixing dodecylbenzene sulfonic acid (0.26 g, 0.80 mmol) and THF (2 cm³) was injected thereto. The mixture was stirred at about 50° C. for about 10 minutes to obtain a reaction product. The reaction product was concentrated under reduced pressure to obtain a viscous liquid. Then, the reaction product was dissolved in THF (1 cm³), and the solution was added dropwise to n-heptane to precipitate a solid product. The solid precipitate was recovered by filtration and dried to obtain [(Bu-Sn)₁₂O₁₄(OH)₆]²⁺[C₁₈H₂₉SO₃⁻]₂ (DSBTOC) as a yellowish solid (0.4 g, 33%).

IR [(KBr): Vₘₐₓ, (cm⁻¹)] 3245, 2975, 2925, 1183, 1127, 1036, 1009, 833, 671, 548

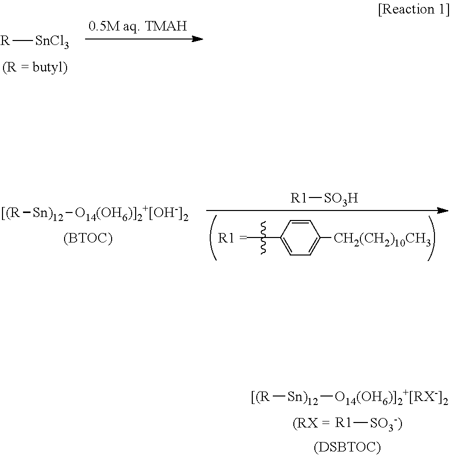

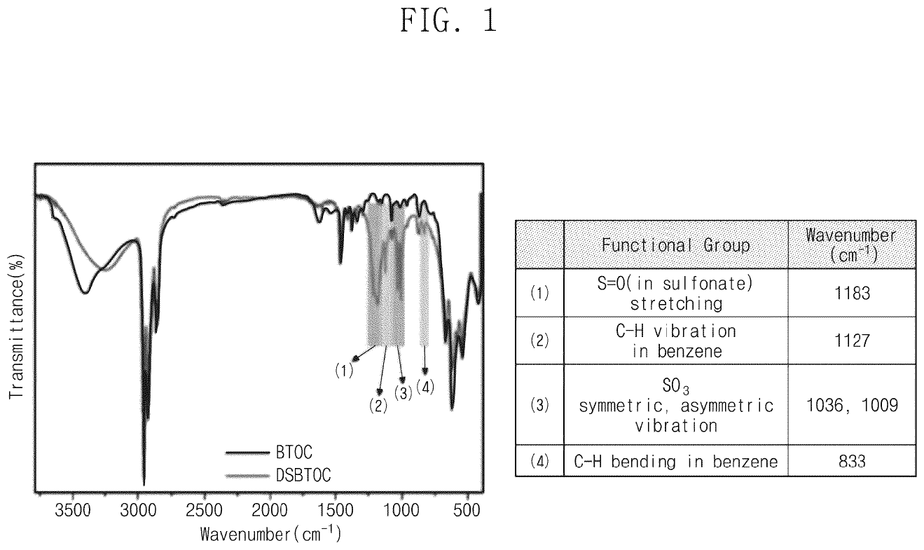

FIG. 1 is a diagram showing Fourier Transform Infrared (FTIR) spectra of BTOC synthesized according to Synthetic Example 1 and DSBTOC synthesized according to Synthetic Example 2.

Referring to FIG. 1, it can be confirmed that a tin-oxo nanoclusters (DSBTOC) represented by Formula 3 was formed according to Synthetic Example 1 and Synthetic Example 2.

### [Synthetic Example 3] Formation of Underlayer Compound Including Crosslinked Material of Tin-Oxo Nanoclusters (DSBTOC)

DSBTOC synthesized according to Synthetic Example 2 was dissolved in a mixture solvent of n-butyl acetate (nBA) and methyl isobutyl ketone (MIBK) in a volume ratio of 1:1 to prepare a DSBTOC solution (3 wt/vol %). The DSBTOC solution thus prepared was applied on a silicon substrate at about 2000 rpm for about 60 seconds by spin coating, and the coated substrate was heated at about 80° C. for about 1 minute to form a thin film (thickness of about 180 nm). After that, ultraviolet of about 254 nm of about 3000 mJ/cm² was irradiated on the thin film, and the thin film was heated at about 250° C. for about 10 minutes. As a result, an underlayer compound having degraded solubility in an organic solvent was formed.

Table 1 shows the solubility of the underlayer compound formed according to Synthetic Example 3 in various organic solvents. In Table 1, “O” means soluble in an organic solvent, and “X” means insoluble in an organic solvent.

TABLE 1

| | | | Heating at 250° C. |
|---|---|---|---|
| | Prior to | After | for 10 minutes |
| | exposure to | exposure to | after exposure to |
| Organic solvent | 254 nm UV | 254 nm UV | 254 nm UV |
| n-Butyl acetate | ◯ | ◯ | X |
| 2-Heptanone | ◯ | ◯ | X |
| Ethyl lactate | ◯ | ◯ | X |
| Methyl ethyl ketone | ◯ | ◯ | X |
| Methyl isobutyl ketone | ◯ | ◯ | X |

Referring to Table 1, it can be confirmed that the underlayer compound formed according to Synthetic Example 3 is insoluble in the organic solvents. Accordingly, it can be confirmed that the underlayer compound formed according to Synthetic Example 3 includes a crosslinked material of the tin-oxo nanoclusters (DSBTOC) represented by Formula 3 from each other.

A multilayered structure according to embodiments of the inventive concept will be explained.

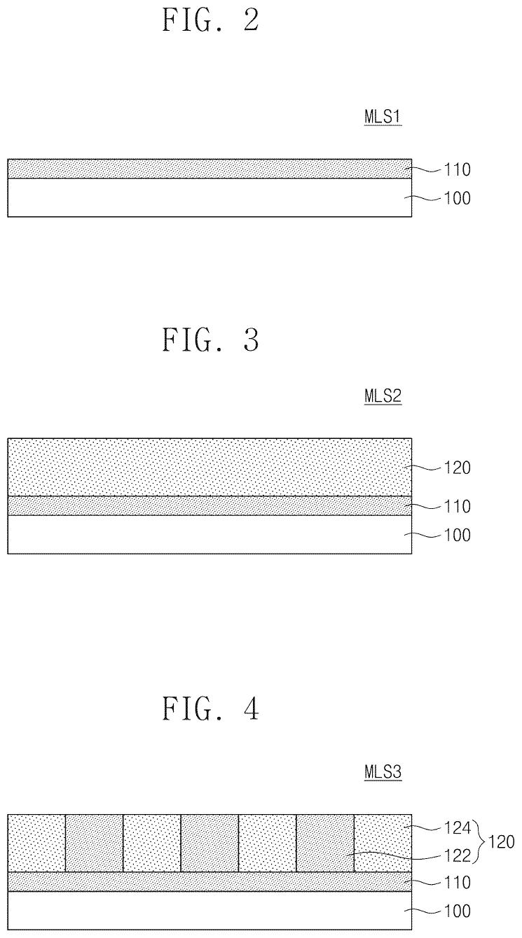

FIG. 2 to FIG. 4 are cross-sectional views showing multilayered structures formed using the underlayer compound according to an embodiment of the inventive concept.

Referring to FIG. 2, a multilayered structure (MLS1) may include a lower layer 100 and an underlayer 110 on the lower layer 100. The lower layer 100 may be an etching target layer, and may be formed by anyone selected from a semiconductor material, a conductive material, or an insulating material, or the combinations thereof. The lower layer 100 may be formed as a single layer or may include stacked multiple layers. The underlayer 110 may include a crosslinked material of tin-oxo nanoclusters represented by Formula 1.

Referring to FIG. 3, a multilayered structure MLS2 may include a lower layer 100, an underlayer 110 on the lower layer 100, and a resist film 120 on the underlayer 110. The lower layer 100 may be substantially the same as the lower layer 100 in FIG. 2. The underlayer 110 may be placed in between the lower layer 100 and the resist film 120 and include a crosslinked material of the tin-oxo nanoclusters represented by Formula 1.

The resist film 120 may include the tin-oxo nanoclusters represented by Formula 1. In an embodiment, the resist film 120 may include the tin-oxo nanoclusters represented by Formula 3. The underlayer 110 may have solubility smaller than the resist film 120 with respect to an organic solvent.

Referring to FIG. 4, a multilayered structure MLS3 may include a lower layer 100, an underlayer 110 on the lower layer 100, and a resist film 120 on the underlayer 110. The lower layer 100 may be substantially the same as the lower layer 100 in FIG. 2. The underlayer 110 may be placed in between the lower layer 100 and the resist film 120 and include a crosslinked material of the tin-oxo nanoclusters represented by Formula 1.

The resist film 120 may include a first part 122 and a second part 124, which are different from each other. The first part 122 may include a crosslinked material of the tin-oxo nanoclusters represented by Formula 1. In an embodiment, the first part 122 may include a crosslinked material of the tin-oxo nanoclusters represented by Formula 3. In an embodiment, the first part 122 may include the same material as the underlayer 110. The tin-oxo nanoclusters in the first part 122 may be crosslinked with the tin-oxo nanoclusters in the underlayer 110 via tin radicals.

The second part 124 may include the tin-oxo nanoclusters represented by Formula 1. In an embodiment, the second part 124 may include the tin-oxo nanoclusters represented by Formula 3. The first part 122 and the underlayer 110 may have solubility smaller than the second part 124 with respect to an organic solvent. A method for manufacturing a semiconductor device according to embodiments of the inventive concept will be explained.

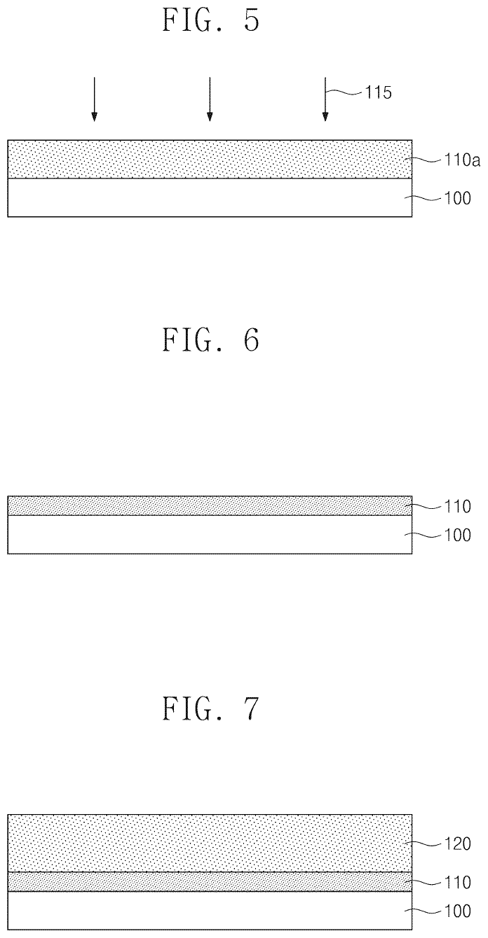

FIG. 5 to FIG. 10 are cross-sectional views showing a method for manufacturing a semiconductor device according to embodiments of the inventive concept.

Referring to FIG. 5, a preliminary underlayer 110a may be formed on a lower layer 100. The lower layer 100 may be an etching target layer and may be anyone selected from a semiconductor material, a conductive material or an insulating material, or the combinations thereof. The lower layer 100 may be formed as a single layer, or may include stacked multiple layers. The preliminary underlayer 110a may include tin-oxo nanoclusters represented by Formula 1.

In an embodiment, the formation of the preliminary underlayer 110a may include applying a thin film including the tin-oxo nanoclusters represented by Formula 1 on the lower layer 100 by using a spin coating method. In another embodiment, the formation of the preliminary underlayer 110a may include depositing a thin film including the tin-oxo nanoclusters represented by Formula 1 on the lower layer 100 by using a chemical vapor deposition method.

A thin film treatment process 115 may be performed on the preliminary underlayer 110a. The thin film treatment process 115 may include at least one of a heating process or an ultraviolet irradiating process. The heating process may be performed, for example, at a temperature of about 180° C. or higher. For example, the thin film treatment process 115 may include sequentially performing the ultraviolet irradiating process and the heating process.

Referring to FIG. 6, by performing of the thin film treatment process 115 on the preliminary underlayer 110a, an underlayer 110 may be formed. The underlayer 110 may include a crosslinked material of the tin-oxo nanoclusters represented by Formula 1. In an embodiment, by the thin film treatment process 115, the tin-oxo nanoclusters in the preliminary underlayer 110a may produce tin radicals, and the tin radicals may be produced by removing the alkyl group (R) from the tin atoms in Formula 1. The tin-oxo nanoclusters represented by Formula 1 may be crosslinked each other via the tin radicals.

According to some embodiments, the formation of the preliminary underlayer 110a and the thin film treatment process 115 may be omitted. In this case, the formation of the underlayer 110 may include the deposition of a thin film including a crosslinked material of the tin-oxo nanoclusters represented by Formula 1 on the lower layer 100 by using a chemical vapor deposition method.

Referring to FIG. 7, a resist film 120 may be formed on the underlayer 110. The resist film 120 may include the tin-oxo nanoclusters represented by Formula 1. In an embodiment, the resist film 120 may include the tin-oxo nanoclusters represented by Formula 3. The resist film 120 may have greater solubility with respect to an organic solvent than the underlayer 110. The formation of the resist film 120 may include, for example, applying a thin film including the tin-oxo nanoclusters represented by Formula 1 on the underlayer 110 by using a spin coating method. The formation of the resist film 120 may further include performing a heat treatment process (for example, a soft baking process) on the applied thin film.

Referring to FIG. 8, an exposing process may be performed on the resist film 120. The exposing process may include aligning a photomask 130 on the resist film 120 and irradiating light 140 on the resist film 120 through the photomask 130. The light 140 may be electron beam or extreme ultraviolet. The resist film 120 may include a first part 122 exposed to the light 140, and a second part 124 unexposed to the light 140. The light 140 may be irradiated to the first part 122 through an opening part 132 of the photomask 130, and may be blocked by the photomask 130 so as not to be irradiated to the second part 124.

The tin-oxo nanoclusters represented by Formula 1 in the resist film 120 may produce tin radicals and secondary electrons by the irradiation of the light 140. The first part 122 of the resist film 120 may include tin radicals produced by the irradiation of the light 140. In the first part 122 of the resist film 120, the tin-oxo nanoclusters represented by Formula 1 may be crosslinked by the tin radicals. Accordingly, the first part 122 of the resist film 120 may include a crosslinked material of the tin-oxo nanoclusters represented by Formula 1. In an embodiment, the first part 122 may include the same material as the underlayer 110. The tin-oxo nanoclusters in the first part 122 may be crosslinked with the tin-oxo nanoclusters in the underlayer 110 by the tin radicals.

The light 140 may not be irradiated to the second part 124 of the resist film 120. Accordingly, the chemical structure of the second part 124 of the resist film 120 may not be changed, and the second part 124 of the resist film 120 may include the tin-oxo nanoclusters represented by Formula 1. As a result, after the exposing process, a solubility difference may occur between the first part 122 and the second part 124.

The underlayer 110 may include tin which is a high extreme ultraviolet light-absorbing element, and the highly absorbing element may absorb the light 140 to emit secondary electrons and produce reactive radicals (for example, tin radicals). During the exposure process, the additional crosslinking bonds of the tin-oxo nanoclusters represented by Formula 1 may occur in the underlayer 110 via the tin radicals produced by the irradiation of the light 140. In addition, during the exposure process, the underlayer 110 may include the secondary electrons produced by the irradiation of the light 140, and the secondary electrons produced in the underlayer 110 may diffuse into the first part 122 of the resist film 120. Accordingly, the crosslinking of the tin-oxo nanoclusters represented by Formula 1 may be promoted in the first part 122 of the resist film 120. In this case, a dosage or light exposure energy required for inducing a solubility switch between the first part 122 and the second part 124 of the resist film 120 may be reduced, and as a result, the sensitivity and resolution of the resist film 120 may be improved.

The tin-oxo nanoclusters of the first part 122 of the resist film 120 may be crosslinked with the tin-oxo nanoclusters in the underlayer 110 by the tin radicals produced by the irradiation of the light 140. Accordingly, the first part 122 of the resist film 120 may be fixed on the underlayer 110 through chemical bonding with the underlayer 110, and the adhesion between the first part 122 of the resist film 120 and the underlayer 110 may increase. As a result, the collapse of a resist pattern which will be explained later, may be suppressed.

Further, the underlayer 110 may include the crosslinked material of the tin-oxo nanoclusters represented by Formula 1, and accordingly, the etching resistance of the underlayer 110 may be improved.

Referring to FIG. 9, after the exposure process, the photomask 130 may be removed. A developing process may be performed on the exposed resist film 120. The developing process may include removing the second part 124 of the resist film 120 using an organic developing solution. The organic developing solution may include, for example, at least one of n-butyl acetate, 2-heptanone, ethyl lactate, methyl ethyl ketone or methyl isobutyl ketone. By the developing process, the second part 124 of the resist film 120 may be selectively removed, and the first part 122 of the resist film 120 may be left as a resist pattern. The resist pattern 122 may be a negative tone pattern.

Referring to FIG. 10, the underlayer 110 and the lower layer 100 may be etched using the resist pattern 122 as an etching mask. The etching of the underlayer 110 and the lower layer 100 may include, for example, a wet or dry etching process. The underlayer 110 may be etched to form an underlayer pattern 110P, and the upper portion of the lower layer 100 may be etched to form a lower pattern 100P. After forming the lower pattern 100P, the resist pattern 122 and the underlayer pattern 110P may be removed. The lower pattern 100P may be a semiconductor pattern, a conductive pattern, or an insulating pattern in a semiconductor device.

### [Experimental Example 1] Formation of Multilayered Structure in which Resist Film Including DSBTOC is Stacked on Underlayer Including Crosslinked DSBTOC

To a mixed solvent of n-butyl acetate (nBA) and methyl isobutyl ketone (MIBK) in a volume ratio of 1:1, DSBTOC synthesized according to Synthetic Example 2 was dissolved to prepare a DSBTOC solution (1.8 wt/vol %). The DSBOTC solution was applied on an underlayer which includes the underlayer compound formed in Synthetic Example 3 at about 2000 rpm for about 60 seconds by spin coating and heated at about 80° C. for about 60 seconds to form a resist thin film. As a result, a multilayered structure (total thickness of about 200 nm) in which a resist thin film including DSBTOC was stacked on top of the underlayer including the crosslinked DSBTOC was formed.

### [Comparative Example 1] Formation of Multilayered Structure in which Resist Film Including DSBTOC is Stacked on Underlayer Including 1,3-Divinyl-1,1,3,3-Tetramethyldisilazane (DVS)

In a mixed solvent of n-butyl acetate (nBA) and methyl isobutyl ketone (MIBK) in a volume ratio of 1:1, the DSBTOC synthesized according to Synthetic Example 2 was dissolved to prepare a DSBTOC solution (1.8 wt/vol %). The DSBTOC solution was applied on a silicon substrate pre-treated with 1,3-divinyl-1,1,3,3-tetramethyldisilazane (DVS) at about 2000 rpm for about 60 seconds by spin coating, and heated at about 80° C. for about 60 seconds to form a resist thin film. As a result, a multilayered structure (total thickness of about 100 nm) in which a resist thin film including DSBTOC was stacked on an underlayer including DVS was formed.

### [Experimental Example 2] Formation of Resist Pattern by Extreme Ultraviolet Lithography Process and Evaluation of Solubility Change of Resist Thin Film

### 1) Multilayered Structure (DSBTOC/crosslinked DSBTOC) Formed in Experimental Example 1

An extreme ultraviolet exposing process was performed on the multilayered structure (DSBTOC/crosslinked DSBTOC) formed in Experimental Example 1. The extreme ultraviolet exposing process was performed under the dosage conditions in a range of about 2 mJ/cm² to about 60 mJ/cm², extracted from a synchrotron accelerator. After the exposing process, a heating process was performed at about 150° C. for about 2 minutes. Then, a developing process was performed using ethyl lactate for about 5 seconds. As a result, the formation of negative tone resist patterns (circular) were confirmed. The thickness of the resist patterns was measured according to the dosage, and the solubility change of the resist thin film was evaluated. The thickness of the resist pattern was measured using an Alpha-step®D-300 stylus profiler, manufactured by Kla-Tencor Co.

### 2) Multilayered Structure (DSBTOC/DVS) Formed in Comparative Example 1

An extreme ultraviolet exposing process was performed on the multilayered structure (DSBTOC/DVS) formed in Comparative Example 1. The extreme ultraviolet exposing process was performed under the dosage conditions in a range of about 2 mJ/cm² to about 60 mJ/cm², extracted from a synchrotron accelerator. After the exposing process, a heating process was performed at about 150° C. for about 2 minutes Then, a developing process was performed using ethyl lactate for about 5 seconds. As a result, the formation of negative tone resist patterns (circular) were confirmed. The thickness of the resist patterns was measured according to the dosage, and the solubility change of the resist thin film was evaluated. The thickness of the resist pattern was measured using an Alpha-step®D-300 stylus profiler, manufactured by Kla-Tencor Co.

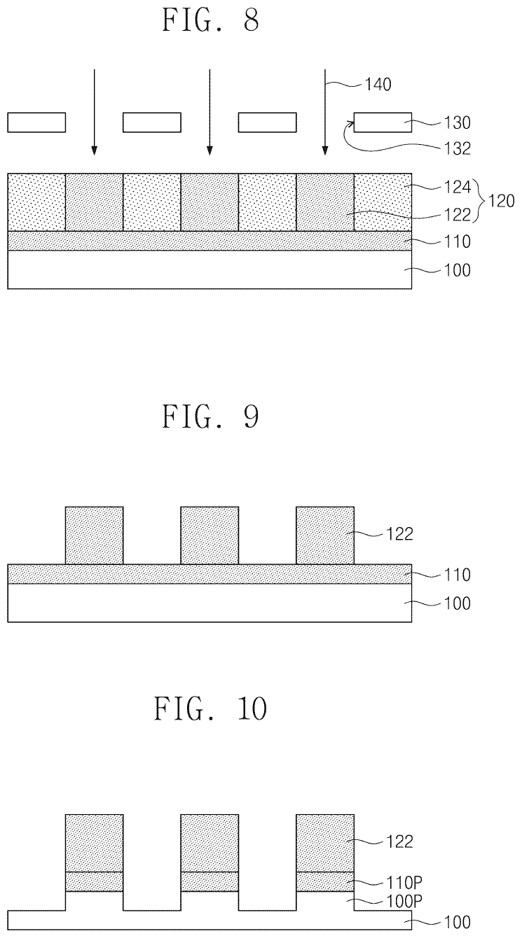

FIG. 11 shows the images of negative tone resist patterns formed by an extreme ultraviolet lithography process of Experimental Example 2.

Referring to FIG. 11, it can be confirmed that negative tone resist patterns having a circular shape were formed by performing an extreme ultraviolet lithography process on the multilayered structure (DSBTOC/crosslinked DSBTOC) formed in Experimental Example 1 and the multilayered structure (DSBTOC/DVS) formed in Comparative Example 1.

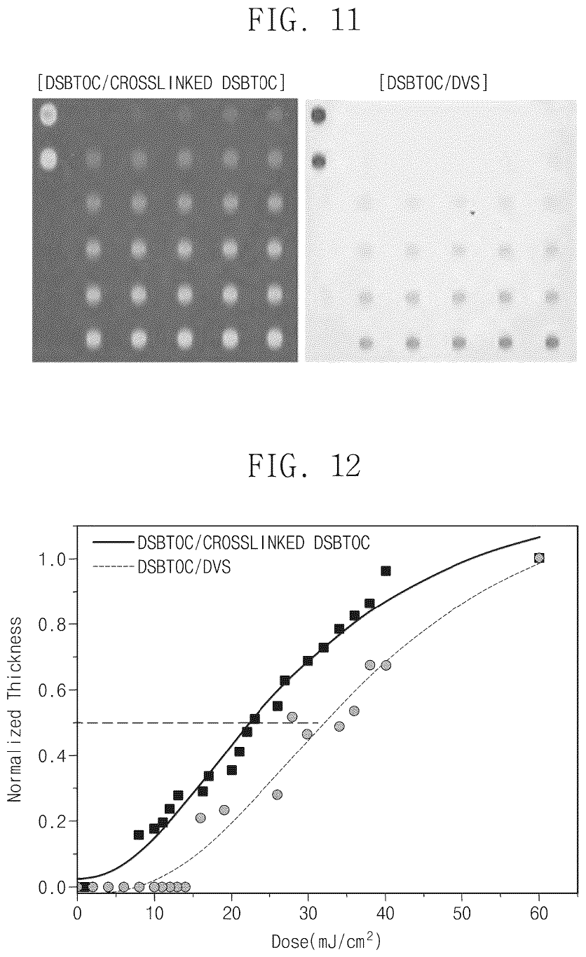

FIG. 12 is a graph showing the evaluation results of the solubility of resist thin films according to Experimental Example 2.

Referring to FIG. 12, in the case of the multilayered structure (DSBTOC/DVS) formed in Comparative Example 1, when extreme ultraviolet of about 32 mJ/cm² was irradiated on the resist thin film, the thickness of the remaining resist pattern could be maintained to about 50% of the thickness of the resist thin film. In the case of the multilayered structure (DSBTOC/crosslinked DSBTOC) formed in Experimental Example 1, when extreme ultraviolet of about 22 mJ/cm² was irradiated on the resist thin film, the thickness of the remaining resist pattern could be maintained to about 50% of the thickness of the resist thin film. From the results it can be confirmed that the underlayer including the crosslinked DSBTOC may complement the light absorption characteristics of the resist thin film to improve the sensitivity of the resist thin film.

According to the inventive concept, an underlayer may include a crosslinked material of the tin-oxo nanoclusters represented by Formula 1, and a resist film may include the tin-oxo nanoclusters represented by Formula 1. The underlayer may have solubility smaller than the resist film with respect to an organic solvent.

Since the underlayer includes tin which is a high light-absorbing element, the underlayer may produce secondary electrons by light irradiation (for example, extreme ultraviolet), the secondary electrons produced in the underlayer may diffuse into the exposed portion of the resist film. Accordingly, the crosslinking of the tin-oxo nanoclusters represented by Formula 1 may be promoted in the exposed part or the resist film. Accordingly, the dosage of an exposure process, required to induce a solubility difference between the exposed part and the unexposed part of the resist film, may be reduced, and as a result, the sensitivity and resolution of the resist film may be improved.

In addition, the tin-oxo nanoclusters in the exposed part of the resist film may make crosslinking bonds with the tin-oxo nanoclusters in the underlayer by tin radicals produced by the light irradiation (for example, extreme ultraviolet irradiation). Accordingly, the exposed part of the resist film may be fixed on the underlayer via the chemical bonding with the underlayer, and the adhesion between the exposed part of the resist film and the underlayer may increase. As a result, the collapse of the resist pattern may be suppressed.

Further, since the underlayer includes a crosslinked material of tin-oxo nanoclusters represented by Formula 1, the etching resistance of the underlayer may be improved.

According to the inventive concept, an underlayer compound which may improve the resolution and sensitivity of a resist film, suppress the collapse of a resist pattern and have improved etching resistance, a multilayered structure formed using the same, and a method for manufacturing a semiconductor device using the same may be provided.

Although the embodiments of the present invention have been described, it is understood that the present invention should not be limited to the embodiments, but various changes and modifications can be made by one ordinary skilled in the art within the spirit and scope of the present invention as hereinafter claimed.

What is claimed is:

1. A multilayered structure comprising:
an underlayer on a lower layer; and
a resist film on the underlayer, wherein
the underlayer comprises a crosslinked material of tin-oxo nanoclusters represented by the following Formula 1:
[(R—Sn)₁₂O₁₄(OH)₆]²⁺[Rx⁻]₂ [Formula 1]
in Formula 1, R is an alkyl group of 1 to 20 carbon atoms, and Rx⁻ is a counter anion and an alkylbenzene sulfonate anion.

2. The multilayered structure of claim 1, wherein the resist film comprises the tin-oxo nanoclusters represented by Formula 1.

3. The multilayered structure of claim 2, wherein the underlayer has solubility in an organic solvent smaller than the resist film.

4. The multilayered structure of claim 1, wherein the underlayer comprises a crosslinked material of the tin-oxo nanoclusters by the generation of tin radicals.

5. The multilayered structure of claim 1, wherein
the resist film comprises a first part and a second part, which are different from each other,
the first part comprises the crosslinked material of tin-oxo nanoclusters represented by Formula 1, and
the second part comprises the tin-oxo nanoclusters represented by Formula 1.

6. The multilayered structure of claim 5, wherein the underlayer and the first part have solubility in an organic solvent smaller than the second part.

7. The multilayered structure of claim 5, wherein the tin-oxo nanoclusters in the first part are crosslinked with the tin-oxo nanoclusters in the underlayer.

8. A method for manufacturing a semiconductor device, the method comprising:
forming an underlayer on a lower layer; and
forming a resist film on the underlayer, wherein
the underlayer comprises a crosslinked material of tin-oxo nanoclusters represented by the following Formula 1:
[(R—Sn)₁₂O₁₄(OH)₆]²⁺[Rx⁻]₂ [Formula 1]
in Formula 1, R is an alkyl group of 1 to 20 carbon atoms, and Rx⁻ is a counter anion and an alkylbenzene sulfonate anion.

9. The method for manufacturing a semiconductor device of claim 8, wherein
the forming of the underlayer comprises:
forming a preliminary underlayer on the lower layer; and
performing a thin film treatment process on the preliminary underlayer,
the preliminary underlayer comprises the tin-oxo nanoclusters represented by Formula 1, and
the thin film treatment process comprises at least one of a heating process or an ultraviolet irradiation process.

10. The method for manufacturing a semiconductor device of claim 9, wherein the forming of the preliminary underlayer comprises applying a thin film including the tin-oxo nanoclusters represented by Formula 1 on the lower layer by using a spin coating method.

11. The method for manufacturing a semiconductor device of claim 9, wherein the forming of the preliminary underlayer comprises depositing a thin film including the tin-oxo nanoclusters represented by Formula 1 on the lower layer by using a chemical vapor deposition method.

12. The method for manufacturing a semiconductor device of claim 8, wherein the forming of the underlayer comprises depositing a thin film including the crosslinked material of tin-oxo nanoclusters represented by Formula 1 on the lower layer by using a chemical vapor deposition method.

13. The method for manufacturing a semiconductor device of claim 8, wherein the resist film comprises the tin-oxo nanoclusters represented by Formula 1.

14. The method for manufacturing a semiconductor device of claim 13, wherein the forming of the resist film comprises applying a thin film including the tin-oxo nanoclusters represented by Formula 1 on the underlayer by using a spin coating method.

15. The method for manufacturing a semiconductor device of claim 8, further comprising performing an exposing process on the resist film,
wherein the exposing process is performed using electron beam or extreme ultraviolet.

16. The method for manufacturing a semiconductor device of claim 15, wherein
the resist film comprises a first part exposed by the exposing process, and a second part unexposed by the exposing process,
the first part comprises the crosslinked material of tin-oxo nanoclusters represented by Formula 1, and
the second part comprises the tin-oxo nanoclusters represented by Formula 1.

17. The method for manufacturing a semiconductor device of claim 16, further comprising performing a developing process to selectively remove the second part of the resist film,
wherein the developing process is performed using an organic developing solution.

18. An underlayer compound for photolithography, the compound comprising a crosslinked material of tin-oxo nanoclusters represented by the following Formula 1:
[(R—Sn)₁₂O₁₄(OH)₆]²⁺[Rx⁻]₂ [Formula 1]
in Formula 1, R is an alkyl group of 1 to 20 carbon atoms, and Rx⁻ is a counter anion and an alkylbenzene sulfonate anion.

19. The underlayer compound for photolithography of claim 18, wherein the tin-oxo nanoclusters are crosslinked each other via tin radicals.

20. The underlayer compound for photolithography of claim 18, wherein Rx⁻ has a structure of the following Formula 2: 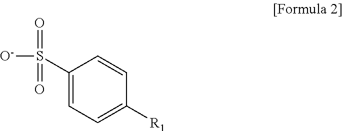
in Formula 2, R₁ is an alkyl group of 1 to 10.
